(19) United States
(12) Patent Application Publication
(10) Pub. No.: US 2008/0157062 A1
(43) Pub. Date: Jul. 3, 2008

(54) Spin transistor

(75) Inventor: Takashi Asatani, Tokyo (JP)

Correspondence Address: OLIFF & BERRIDGE, PLC, P.O. BOX 320850, ALEXANDRIA, VA, 22320-4850, US

(73) Assignee: TDK CORPORATION, Tokyo (JP)

(21) Appl. No.: 12/003,032

(22) Filed: Dec. 19, 2007

(30) Foreign Application Priority Data
Dec. 28, 2006 (JP) 2006-355360

(51) Int. Cl. H01L 29/12

(52) U.S. Cl. 257/39; 257/E29.068

(57) ABSTRACT

A spin transistor 1 is a spin transistor 1 having a source S of a ferromagnetic material, a drain D of a ferromagnetic material, a semiconductor SM on which the source S and the drain D are disposed and which forms a Schottky contact with the source S, and a gate electrode GE disposed through a gate insulating layer GI on the semiconductor SM, wherein a tunnel barrier insulating layer TI constituting a tunnel barrier is interposed between the semiconductor SM and the drain D.

### BACKGROUND OF THE INVENTION

1. Field of the Invention

The present invention relates to a spin transistor.

2. Related Background Art

There is currently much interest in research on spin electronics (spintronics). The spin transistors are transistors making use of spins of electrons, and are expected to bring about the innovation of new technology. The spin transistors can also be used as memory elements of new structure (Patent Document 1: Japanese Patent Application Laid-open No. 2004-111904; Patent Document 2: International Publication WO2004/079827) and as multi-functional logic circuitry (Patent Document 3: International Publication WO2004/086625). Furthermore, since they are produced by use of a magnetic material process, it can also be contemplated that they are used as control elements of magnetic elements.

Particularly, Patent Document 1 suggests the spin transistors of various structures and, especially, FIG. 11 in Patent Document 1 discloses a spin transistor in which a nonmagnetic semiconductor layer is disposed between two ferromagnetic metals (FM) forming a source and a drain and in which an electrode is disposed through a gate insulating layer on this semiconductor layer. A Schottky contact or junction is formed at an interface between the semiconductor layer and each of the source and the drain.

Spin-polarized electrons are injected from the source through the Schottky barrier into the semiconductor layer. The direction of spin polarization of the electrons injected into the semiconductor layer is dependent on the magnetization direction of the source and the spin polarizability of the carriers injected into the semiconductor layer is dependent on the spin polarizability of the source.

Electrons injected through a channel of the semiconductor layer into the drain are scattered depending upon the direction of polarization thereof. In other words, the electrons injected into the semiconductor channel as tunneling from the source through the Schottky barrier undergo spin-dependent scattering on the drain side. When the directions of magnetizations of the source and drain are parallel, the magnetic resistance becomes small between the source and the drain, and the magnetic resistance becomes large in the antiparallel case.

### SUMMARY OF THE INVENTION

It is, however, expected that in the conventional spin transistor an interface potential between the semiconductor layer and the drain is changed by only about several ten mV due to the magnetic resistance. Therefore, when the drain-source voltage is several V, a current change rate of current changing dependent on the magnetizations of the drain and source is not more than several %. The spin transistor of this structure is significant as an academic spin transistor, but a further improvement is needed for application to industrially practical spin transistors.

The present invention has been accomplished in view of this problem, and an object of the invention is to provide a spin transistor capable of achieving a practical current change rate.

In order to solve the above-described problem, a spin transistor according to the present invention is a spin transistor comprising: a source of a ferromagnetic material; a drain of a ferromagnetic material; a semiconductor on which the source and the drain are disposed and which forms a Schottky contact with the source; and a gate electrode disposed directly or through a gate insulating layer on the semiconductor, wherein a tunnel barrier insulating layer constituting a tunnel barrier is interposed between the semiconductor and the drain.

In this spin transistor, a positive potential is applied to the gate electrode to form an n-type channel in the semiconductor corresponding to this positive potential and at the same time, the thickness of the potential barrier formed by the Schottky contact between the source and the semiconductor is decreased to increase electrons flowing into the channel of the semiconductor. Since the source is made of the ferromagnetic material, the electrons injected from the source into the semiconductor have a spin polarized in one direction.

When the direction of magnetization of the drain is opposite to that of the source, most of the electrons are reflected by the existence of the tunnel barrier insulating layer and do not flow into the drain.

On the other hand, when the direction of magnetization of the drain is identical with that of the source, the electrons injected into the semiconductor migrate through the tunnel barrier insulating layer into the drain.

A change rate of amount of electrons flowing into the drain, i.e., a current change rate of the spin transistor becomes extremely larger than before, in accordance with the direction of magnetization of the drain. Therefore, the spin transistor can be applied as a practical spin transistor.

It can also be contemplated that the direction of magnetization of the drain is controlled by self-injection of the spin into the drain, but this spin transistor is preferably configured to further comprise control means for controlling the direction of magnetization of the drain. For example, the control means is a wire extending in a direction perpendicular to the direction of magnetization of the drain and disposed near the drain, and when an electric current is supplied thereto, the direction of magnetization in the drain can be controlled by the direction of flow of the electric current.

Preferably, the tunnel barrier insulating layer contains at least one selected from the group consisting of SiO₂, Al₂O₃, NiO, CoFeO, MgO, CaF₂, and ZnO.

SiO₂ is suitably applicable because it can be prepared with high quality by thermal oxidation of Si. Al₂O₃ is also suitably applicable because it has so high a barrier height as to make conduction unlikely to occur due to thermal excitation of electrons. NiO is suitably applicable because it is easy to achieve a low resistance. CoFeO is suitably applicable because it is easy to achieve a low resistance. Furthermore, MgO is suitably applicable because the polarizability can be better than with SiO₂; CaF₂ is suitably applicable because the lattice constant thereof matches that of Si; ZnO is suitably applicable because it is easy to achieve a low resistance.

In the spin transistor of a first type, preferably, the source is a ferromagnetic metal, a conductivity type of the semiconductor is the n-type, a work function φm of the ferromagnetic metal and a work function φs of the semiconductor satisfy a relation of φm>φs, the source and the semiconductor form a Schottky contact, and a thickness of a potential barrier formed by the Schottky contact can be reduced to not more than a thickness in which a tunnel effect is caused according to a potential applied to the gate electrode.

Namely, when the work functions satisfy the relation of φm>φs, a spike-like potential barrier is formed between the source and the semiconductor. This potential barrier makes electrons unlikely to flow from the source into the semiconductor in an equilibrium state before a positive potential is applied to the gate electrode (or before a positive voltage is placed between the source and the gate). When the gate potential is raised, the energy of the semiconductor is lowered according to the applied potential, and thus the thickness of the spike-like potential barrier is decreased to permit flow of electrons from the source into the semiconductor by the tunnel effect.

In the spin transistor of a second type, preferably, a conductivity type of the semiconductor is the p-type, a work function φm of the ferromagnetic metal and a work function φs of the semiconductor satisfy a relation of φm<φs, the source and the semiconductor form a Schottky contact, and a potential at a lower end of a conduction band of the semiconductor can be increased so as to permit flow of electrons from the source into the semiconductor, according to a potential applied to the gate electrode.

Namely, when the work functions satisfy the relation of φm<φs, a potential barrier against holes is formed between the upper end of the valence band and the metal, while a gentle energy barrier against electrons exists near the interface of the semiconductor to the metal; therefore, the carriers do not move and in the equilibrium state electrons do not flow from the source into the semiconductor. When the gate potential is raised, electrons gather immediately below the gate electrode according to the increase of the gate potential and with it, the gentle energy barrier is lowered according to the applied potential; in other words, the potential at the lower end of the conduction band increases to permit flow of electrons from the source into the semiconductor

As described above, the spin transistor of the present invention is able to achieve a practical current change rate.

### BRIEF DESCRIPTION OF THE DRAWINGS

FIG. 1 is a drawing showing a vertical sectional configuration of spin transistor 1 according to the first embodiment.

FIG. 2 is an energy band diagram of the spin transistor.

FIG. 3 is an energy band diagram of the spin transistor.

FIG. 4 is an energy band diagram of the spin transistor.

FIG. 5 is an energy band diagram of the spin transistor.

FIG. 6 is an energy band diagram of the spin transistor.

FIG. 7 is an energy band diagram of the spin transistor.

FIG. 8 is a drawing showing a vertical sectional configuration of spin transistor 1 according to the second embodiment.

### DESCRIPTION OF THE PREFERRED EMBODIMENTS

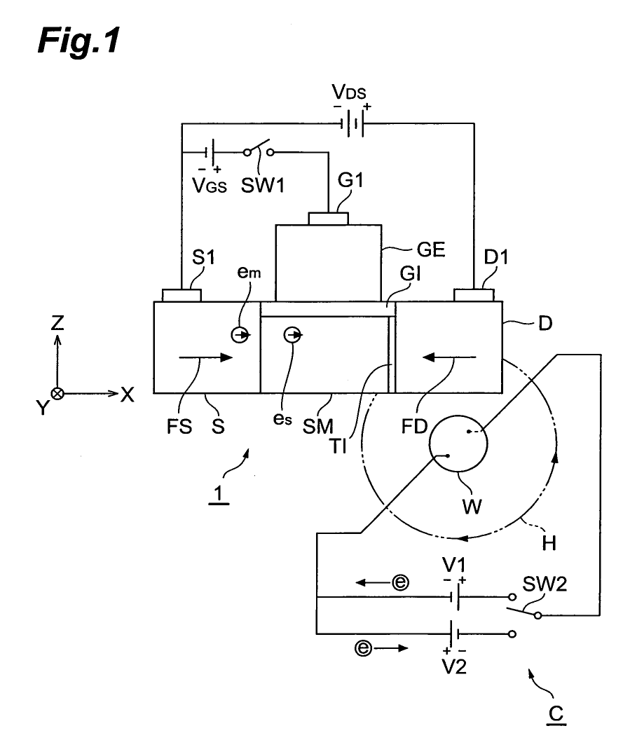

Spin transistors according to embodiments will be described below. The same elements will be denoted by the same reference symbols, without redundant description. (First Embodiment) FIG. 1 is a drawing showing a vertical sectional configuration of spin transistor 1 according to the first embodiment.

The spin transistor 1 is a spin transistor 1 comprising a source S of a ferromagnetic material; a drain D of a ferromagnetic material; a semiconductor SM on which the source S and the drain D are disposed and which forms a Schottky contact with the source S; and a gate electrode GE disposed through a gate insulating layer GI on the semiconductor SM, wherein a tunnel barrier insulating layer TI constituting a tunnel barrier is interposed between the semiconductor SM and the drain D.

Contact layers S1, D1, G1 for application of a bias are provided in electric contact on the source S, on the drain D, and on the gate electrode GE, respectively. A constant voltage V_{DS} is applied between source S and drain D through the contact layers S1, D1, and a gate voltage V_{GS} is applied between source S and gate electrode GE through the contact layers S1, G1. The presence or absence of application of the gate voltage V_{GS} is determined by switch SW1 interposed between gate electrode GE and source S.

In a conventional semiconductor MOSFET (Metal-Oxide-Semiconductor Field Effect Transistor), the side where carriers are generated is normally defined as a “source,” and a conductivity type of the semiconductor immediately below the gate is different from that of the source.

In the spin transistors of the embodiments of the present invention, carriers are spin-polarized electrons or holes, and the side from which the carriers flow into the semiconductor SM is defined as the source, regardless of the conductivity type of the semiconductor SM. When a hole is injected from the source into the semiconductor, it is assumed that the spin of the hole is the one opposite to that of an electronic state of a missing electron.

In the same drawing, the direction FS of magnetization of the source S is aligned with the positive direction of the X-axis, and the direction FD of magnetization of the drain D is aligned with the negative direction of the X-axis. The thickness direction of the semiconductor SM is aligned with the direction of the Z-axis. A controller C for controlling the direction FD of magnetization of the drain D is arranged near the drain D. The controller C in the present example is provided with a wire W extending in the direction (Y-axis direction) perpendicular to the direction FD of magnetization of the drain D, and located in the vicinity of the drain D, and when an electric current is allowed to flow through the wire W, a magnetic field H is generated in a direction around the longitudinal direction of the wire W. The direction of the magnetic field H has a component along the positive direction or the negative direction of the X-axis, at the position of the drain D. The direction FD of magnetization of the drain D is controlled by the magnetic field H. Namely, the direction FD of magnetization in the drain D can be controlled by the direction of the electric current supplied to the wire W.

Power supplies V1, V2 for control of the magnetic field are connected in mutually opposite polarities to one end of the wire W and a switch SW2 to switch the presence/absence of electric current and the direction of the electric current is connected between the other end of the wire W and each power supply V1, V2. When electrons e are supplied from the power supply V1 to the wire W, an electric current flows in the opposite direction thereto, and the counterclockwise magnetic field H is generated around the wire W, according to the right-handed screw rule. On the other hand, when electrons e are supplied from the power supply V2 to the wire W, an electric current flows in the opposite direction thereto and the clockwise magnetic field H is generated around the wire W, according to the right-handed screw rule.

Materials and special notes applicable to each of the elements are as described below.

TABLE 1

| Element | Material | Note |
|---|---|---|
| source S | ferromagnetic material | |
| | alloy containing one of | |
| | Fe, Co, Ni, and Gd, or | |
| | alloy containing two or | |
| | more of them | |
| | Examples: | |
| | CoFe | |
| | CoFeB | |
| | Co₂MnGe (Heusler alloy) | |
| semiconductor SM | Si | the conductivity type is the n-type |
| | GaAs | or the p-type. |
| | other compound | the impurity content is preferably |
| | semiconductors | 1 × 10¹⁴ cm⁻³-1 × 10¹⁵ cm⁻³. |
| drain D | ferromagnetic material | |
| | the same materials as the | |
| | source materials | |
| gate insulating layer GI | SiO₂ | |
| | Al₂O₃ | |
| | NiO | |
| | CoFeO | |
| | MgO | |
| | ZnO | |
| gate electrode GE | Al | |
| | Cu | |
| | W | |
| | silicides of the above | |
| | metals | |
| | polysilicon | |
| tunnel barrier insulating layer | SiO₂ | the thickness should be not more |
| TI | Al₂O₃ | than the one in which the tunnel |
| | NiO | effect is caused. |
| | CoFeO | the thickness is preferably not |
| | MgO | more than 1 nm. |
| | ZnO | |
| contact layers S1, D1, G1 | Al | |
| | Cu | |
| | W | |
| | silicides of the above | |
| | metals | |
| | polysilicon | |
| wire W | Au | |
| | Al | |
| | Cu | |
| | W | |
| | polysilicon | |

Preferably, the tunnel barrier insulating layer TI contains at least one selected from the group consisting of SiO₂, Al₂O₃, NiO, CoFeO, MgO, CaF₂, and ZnO.

SiO₂ is suitably applicable because it can be prepared with high quality by thermal oxidation of Si. Al₂O₃ is also suitably applicable because it has so high a barrier height as to make conduction unlikely to occur due to thermal excitation of electrons. NiO is suitably applicable because it is easy to achieve a low resistance. CoFeO is suitably applicable because it is easy to achieve a low resistance. Furthermore, MgO is suitably applicable because the polarizability can be better than with SiO₂; CaF₂ is suitably applicable because the lattice constant thereof matches that of Si; ZnO is suitably applicable because it is easy to achieve a low resistance.

The gate insulating layer GI can be made of a nitride such as AlN or GaN, or a fluoride such as CaF₂, as well as the oxides.

Next, the operation of the above-described spin transistor 1 will be described.

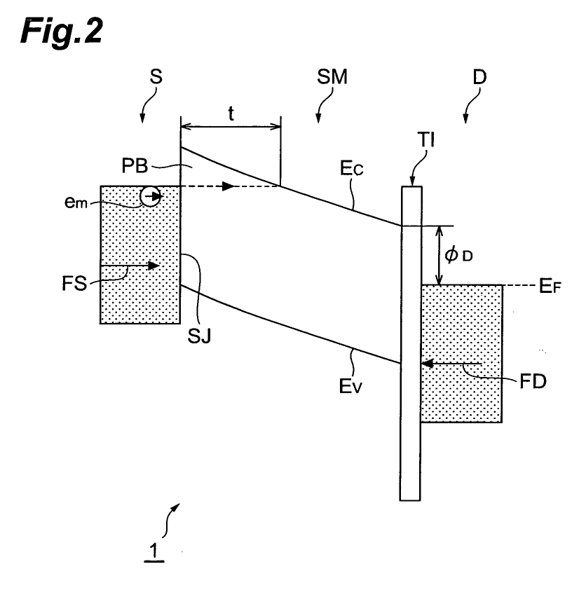

FIG. 2 is an energy band diagram of the semiconductor SM immediately below the gate electrode GE and the source S and drain D adjacent thereto in the spin transistor 1 shown in FIG. 1. FIG. 2 shows a case where the conductivity type of the semiconductor SM is the n-type and where the switch SW1 in FIG. 1 is disconnected to apply no voltage to the gate electrode GE. In the energy band diagram, the energy becomes higher upward in the positive vertical direction, and the potential becomes higher downward in the negative vertical direction.

An electron em injected into the source S of the ferromagnetic metal comes to have a spin polarized in the same direction as the direction FS of magnetization of the source S (provided that the sign of the electron is negative). A thickness t of a potential barrier (depleted layer) PB formed by the Schottky contact SJ between source S and semiconductor SM is larger than a thickness in which the tunnel effect is caused, and thus electrons em in the source S are not injected into the semiconductor SM. In the same drawing Ec indicates the energy level at the lower end of the conduction band of the semiconductor SM, and Ev the energy level at the upper end of the valence band.

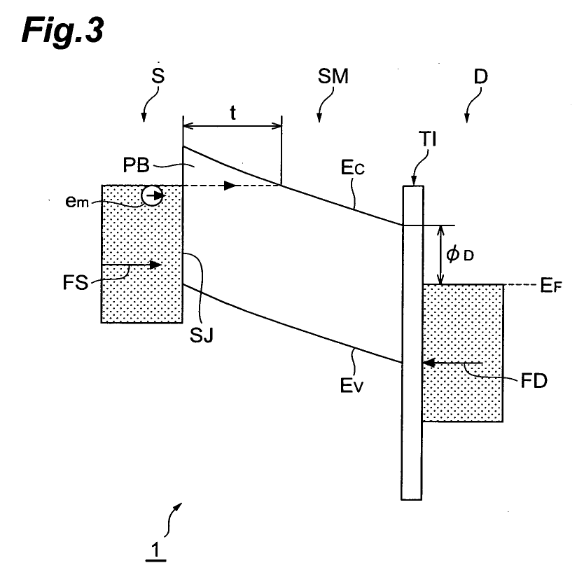

FIG. 3 is an energy band diagram at the same position as in FIG. 2, in the spin transistor 1. FIG. 3 shows a case where the switch SW1 in FIG. 1 is connected to apply a voltage to the gate electrode GE.

When a positive potential is applied to the gate electrode GE in FIG. 1, an n-type channel is formed immediately below the gate electrode GE in the semiconductor SM corresponding to this positive potential, and at the same time, the thickness t of the potential barrier PB formed by the Schottky contact SJ between source S and semiconductor SM becomes smaller to increase electrons es flowing into the channel of the semiconductor SM.

Since the source S is made of the ferromagnetic material, the electrons es injected from the source S into the semiconductor SM have the spin in one direction. A ratio of a state density of electrons with the spin parallel to the direction FS of magnetization to a state density of electrons with the spin antiparallel thereto becomes equal to a ratio of the number of electrons parallel to the direction FS of magnetization to the number of antiparallel electrons.

When the direction FD of magnetization of the drain D is opposite to the direction FS of magnetization of the source S, most of the electrons es are reflected by the existence of the tunnel barrier insulating layer TI and do not flow into the drain D.

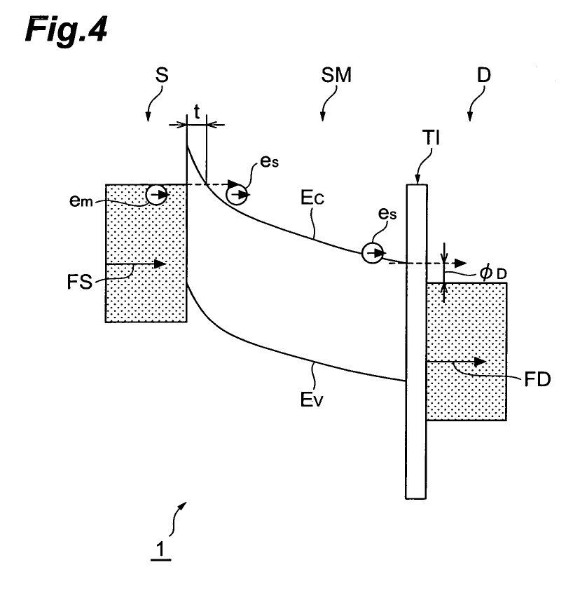

FIG. 4 is an energy band diagram at the same position as in FIG. 3, in the spin transistor 1. FIG. 4 shows a state in which the switch SW1 in FIG. 1 is connected to apply the voltage to the gate electrode GE and in which the switch SW2 is connected to the power supply V2 to generate the clockwise magnetic field H around the wire W, thereby inverting the direction FD of magnetization of the drain D. The direction FD of the inverted magnetization can be returned into the original state by connecting the switch SW2 in FIG. 1 to the power supply V1. In the states of FIG. 2 and FIG. 3, the switch SW2 may be connected to the power supply V1 and, where the direction FD of magnetization in the original state is the positive direction of the X-axis, the switch SW2 may be in a disconnected state.

In the case of the state shown in FIG. 4, the direction FD of magnetization of the drain D becomes identical with the direction FS of magnetization of the source S, whereby the electrons es injected into the semiconductor SM migrate through the tunnel barrier insulating layer TI into the drain D.

The ferromagnetic material making up the drain D is one having spontaneous magnetization and having a magnetic moment even in a state in which no external magnetic field exists. The energy in the state of electrons with the spin parallel to the direction of the magnetic moment is different from that in the state of electrons with the spin antiparallel thereto. For this reason, the state density on the Fermi surface of metal differs depending upon the directions of spins of electrons. If the state density on the Fermi surface of the electron state in which the spin magnetic moment is in the direction parallel to the spontaneous magnetization is larger than the state density on the Fermi surface of the electron state in which the spin magnetic moment is in the direction antiparallel to the spontaneous magnetization, the spin polarizability of the ferromagnetic material is positive. Since the number of conducted electrons is proportional to the state density on the Fermi surface of metal, the number of conducted electrons differs depending upon the directions of spins.

When electrons flow from the semiconductor SM into the drain D, the TMR effect is caused. Namely, when electrons migrate to tunnel the tunnel barrier into the drain D of the ferromagnetic material, the probability of electrons tunneling the tunnel barrier varies depending upon relative directions between the direction of the spin of electrons and the direction FD of magnetization of the ferromagnetic material. This induces an electric current change so as to cause a resistance change. A resistance change rate on this occasion is determined depending upon a ratio of the state density of the state in which the spin magnetic moment of electrons is parallel to the magnetization direction of the ferromagnetic material, on the Fermi surface of electrons in the ferromagnetic material making up the drain D, to the state density of the antiparallel state.

In the spin transistor 1 of the above-described structure, a change rate of amount of electrons flowing into the drain D according to the direction FD of magnetization of the drain D, i.e., a current change rate of the spin transistor 1 becomes extremely larger than that before. Therefore, the spin transistor 1 can be applied as a practical spin transistor.

In the foregoing spin transistor 1, as described above, the source S is made of the ferromagnetic metal, the conductivity type of the semiconductor SM is the n-type, and the work function φm of this ferromagnetic metal and the work function φs of the semiconductor SM satisfy the relation of φm>φs.

Namely, the source S and the semiconductor SM form the Schottky contact SJ, and the thickness t of the potential barrier PB formed by the Schottky contact SJ can be reduced to not more than the thickness in which the tunnel effect is caused according to the potential applied to the gate electrode GE.

When the work functions satisfy the relation of φm>φs, the spike-like potential barrier PB is formed between the source S and the semiconductor SM. This potential barrier PB keeps electrons em unlikely to flow from the source S into the semiconductor SM in the equilibrium state (FIG. 2) before the positive potential is applied to the gate electrode GE (or before the positive voltage is placed between the source and the gate). When the gate potential is raised (FIG. 3 or FIG. 4), the energy of the semiconductor SM is lowered according to the applied potential, and thus the thickness t of the spike-like potential barrier PB decreases to allow electrons em to flow from the source S into the semiconductor SM by the tunnel effect.

It can also be contemplated that the direction FD of magnetization of the drain D is controlled by self-injection of the spin from the source into the drain.

With reference to FIGS. 2 to 4, a potential difference φ_{D} exists between the Fermi level EF of the metal making up the drain D and the lower end of the conduction band Ec of the semiconductor SM adjacent thereto. The application of the gate voltage bends the energy band of the semiconductor SM, so as to decrease the thickness of the potential barrier PB, whereby electrons em come to tunnel from the source S into the conduction band of the semiconductor to cause flow of an electric current through the spin transistor 1. In the case of diffusive conduction or, in an ideal case where no scattering occurs at all in the drain D, electrons es migrate from the semiconductor SM into the drain D by ballistic transport, and as a consequence of this migration the potential difference φ_{D} is determined at the interface between the drain D and the semiconductor SM.

When the magnetization directions FS, FD of the source S and the drain D are parallel to each other (FIG. 4), the potential difference (PD at the drain interface becomes smaller than that when they are antiparallel (FIG. 2 or FIG. 3), but a difference between them is approximately a spin accumulation potential in the drain D where the conduction between the semiconductor SM and the drain D is diffusive conduction; the difference is approximately a thermal energy at room temperature where the conduction between the semiconductor SM and the drain D is heat radiation conduction.

If the aforementioned tunnel barrier insulating layer TI is absent, the accumulation potential of the ferromagnetic material is about several mV unless the ferromagnetic material is either a ferromagnetic semiconductor or a perfect half metal. When the conduction between semiconductor SM and drain D is heat radiation conduction, the thermal energy at room temperature is about several ten meV, and thus a change (decrease) in the potential difference at the drain interface due to the relative change of the magnetization directions of the source S and the drain D is also at most about several ten mV. Since this is small in comparison with the voltage of several V normally applied between source S and drain D, a change (increase) in the internal electric field in the semiconductor between source S and drain D is small. As a result, a change (increase) in the electric current is also small relative to the case where the magnetization directions of the source S and the drain D are antiparallel.

On the other hand, the tunnel barrier insulating layer TI is present in the present embodiment, and thus the current change rate becomes larger. Namely, when the conduction between semiconductor SM and drain D is tunneling, the probability of the tunneling is strongly dependent upon the relative directions between the direction of the spin of carriers and the magnetization direction of the drain D, and thus we can expect a large current change. The voltage (=several hundred mV) applied at the interface between drain D and semiconductor SM is expected to become much larger than the potential difference φ_{D} (several ten mV) caused by the diffusive conduction at the interface between semiconductor SM and the drain D. Supposing the source S-drain D voltage is about 1 V, the control of the direction FD of magnetization leads to a change in the semiconductor SM-drain D voltage, i.e., a change in the electric current flowing through the transistor, at a normegligible level in comparison with 1 V.

As the potential difference φ_{D} decreases, the thickness t of the potential barrier PB becomes much smaller, and the probability of injection of electrons em into the semiconductor SM is further increased.

The below will describe the case where the conductivity type of the semiconductor SM is the p-type. The structure of spin transistor 1 in this case is the same as that shown in FIG. 1.

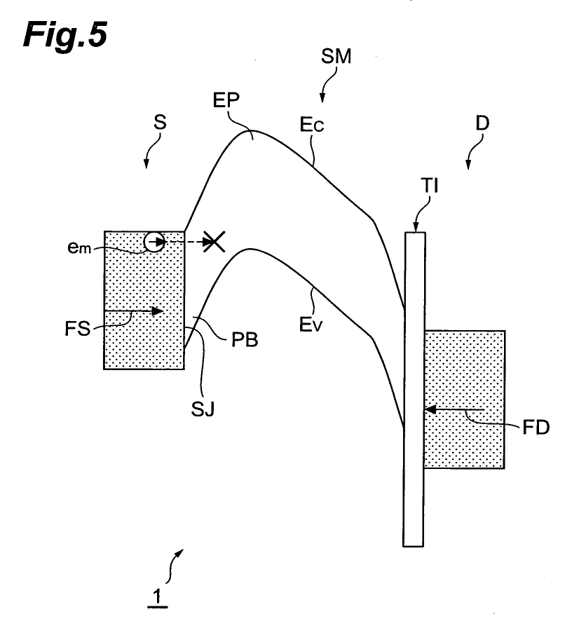

FIG. 5 is an energy band diagram of the semiconductor SM immediately below the gate electrode GE, and the source S and drain D adjacent thereto in the spin transistor 1 shown in FIG. 1. FIG. 5 shows a case where the conductivity type of the semiconductor SM is the p-type and where the switch SW1 in FIG. 1 is disconnected to apply no voltage to the gate electrode GE.

The interface between source S and semiconductor SM forms a Schottky contact SJ and, without application of the gate voltage, holes in the semiconductor SM are not injected into either of the source S and drain D and electrons em in the source S cannot migrate over a peak of a bend of the energy band of the semiconductor SM and are thus not injected into the semiconductor SM.

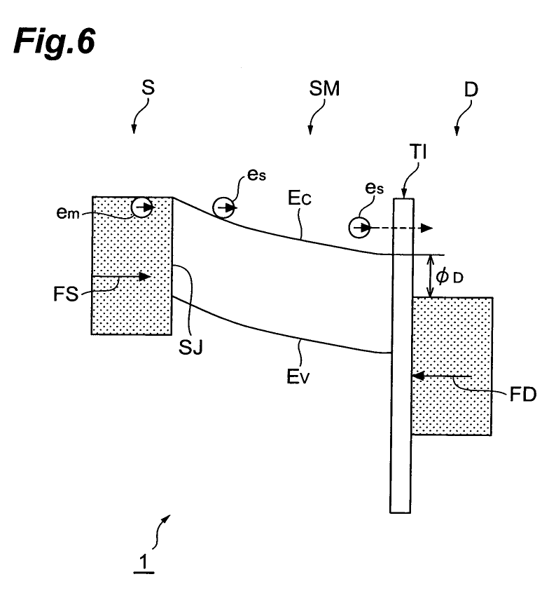

FIG. 6 is an energy band diagram at the same position as in FIG. 5, in the spin transistor 1. FIG. 6 shows a case where the switch SW1 in FIG. 1 is connected to apply the voltage to the gate electrode GE.

When a positive potential is applied to the gate electrode GE in FIG. 1, an n-type channel is formed immediately below the gate electrode GE in the semiconductor SM corresponding to this positive potential and at the same time, the height (energy) of the peak of the energy band of the semiconductor SM becomes lowered, whereby the electrons em in the source S are injected into the semiconductor SM. Since the source S is made of the ferromagnetic material, the electrons es injected from the source S into the semiconductor SM have the spin in one direction.

When the direction FD of magnetization of the drain D is opposite to the direction FS of magnetization of the source S, most of the electrons es are reflected by the existence of the tunnel barrier insulating layer TI and do not flow into the drain D.

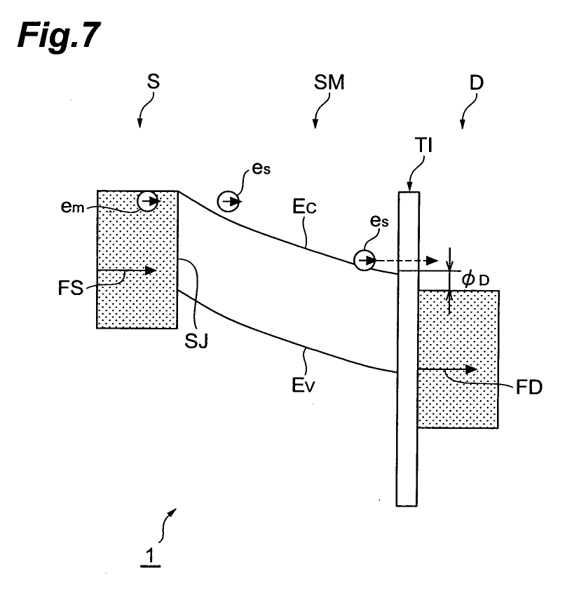

FIG. 7 is an energy band diagram at the same position as in FIG. 5, in the spin transistor 1. FIG. 7 shows a state in which the switch SW1 in FIG. 1 is connected to apply the voltage to the gate electrode GE and in which the switch SW2 is connected to the power supply V2 to generate the clockwise magnetic field H around the wire W, thereby inverting the direction FD of magnetization of the drain D. The direction FD of the inverted magnetization can be returned into the original state by connecting the switch SW2 to the power supply V1. In the states of FIG. 5 and FIG. 6, the switch SW2 may be connected to the power supply V1 and, where the direction FD of the magnetization in the original state is the positive direction of the X-axis, the switch SW2 may be in a disconnected state.

In the case of the state shown in FIG. 7, the direction FD of magnetization of the drain D becomes identical with the direction FS of magnetization of the source S, and thus electrons es injected into the inversion channel of the semiconductor SM migrate through the tunnel barrier insulating layer TI into the drain D. When the direction FD of magnetization of the drain D is parallel to the direction FS of magnetization of the source S, the potential difference φ_{D} at the drain interface is smaller than that in the antiparallel case.

In the spin transistor 1 in which the conductivity type of the semiconductor SM is the p-type, as described above, the source S is the ferromagnetic metal, the work function φm of the ferromagnetic metal making up the source S, and the work function φs of the semiconductor SM satisfy the relation of φm<φs, the source S and the semiconductor SM form the Schottky contact, and the potential at the lower end of the conduction band of the semiconductor SM can be increased so as to allow flow of electrons from the source S into the semiconductor SM, according to the potential applied to the gate electrode GE.

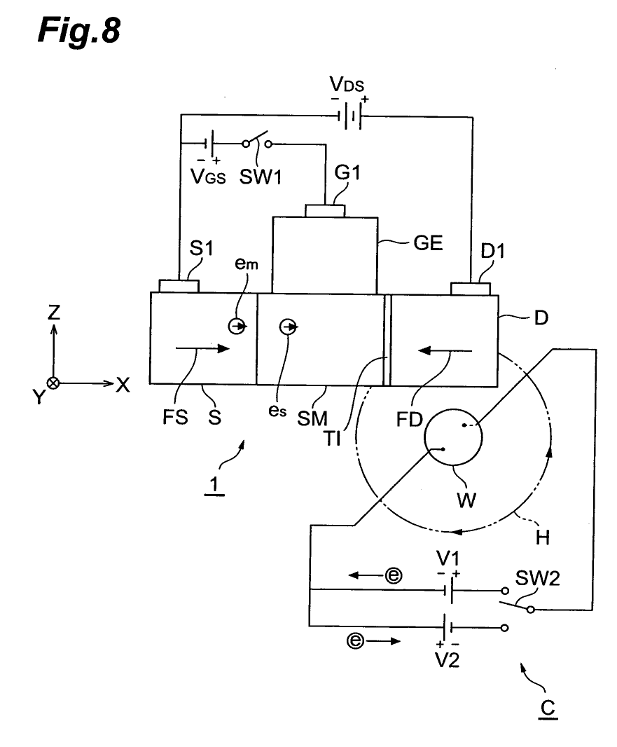

When the work functions satisfy the relation of φm<φs, the potential barrier PB against holes is made between the upper end Ev of the valence band and the metal. On the other hand, since a gentle energy barrier EP against electrons em is present near the interface of the semiconductor SM to the metal (cf. FIG. 5), migration of carriers does not occur, and electrons do not flow from the source S into the semiconductor SM, in the equilibrium state. When the gate potential is raised, electrons gather immediately below the gate electrode GE according to the rise of the gate potential, and with this movement, the gentle energy barrier EP becomes lowered according to the applied potential. In other words, the potential at the lower end of the conduction band Ec increases so as to permit flow of electrons em from the source S into the semiconductor SM. (Second Embodiment) FIG. 8 is a drawing showing a vertical sectional configuration of the spin transistor according to the second embodiment.

As shown in the same drawing, the gate electrode GE may be disposed directly on the semiconductor SM. The spin transistor of the present embodiment is different in this point from that shown in FIG. 1. The conduction channel is the n-type only immediately below the gate and a source-drain current flows with no gate voltage being applied. When a negative voltage is applied to the gate, the n-type region is inverted to disappear, whereby the source-drain current is interrupted. The gate electrode GE and the semiconductor SM form a Schottky contact. In this case, the spin transistor has the MESFET (Metal Semiconductor Field Effect Transistor) structure. When the semiconductor SM is Si, the known materials to form a Schottky contact with Si are Al, Mo, Pt, W, TiSi₂, WSi₂, Au, and so on. When the semiconductor SM is a compound semiconductor, e.g., when it is GaN, materials to form a Schottky contact with GaN can be Ti/Au, Au, Ti, and so on. When the semiconductor SM is diamond, materials to form a Schottky contact therewith can be Al and Au. In the aforementioned example, spin-polarized electrons are injected into the semiconductor SM; however, this can also be arranged as follows; the materials of the source and drain are, for example, Co, CoFe, Ni, or the like, the conductivity type of each semiconductor SM in the foregoing examples is reversed, and the polarity of the applied voltage is reversed, whereby polarized holes are injected into the semiconductor SM.

What is claimed is:

1. A spin transistor comprising:
a source of a ferromagnetic material;
a drain of a ferromagnetic material;
a semiconductor on which the source and the drain are disposed and which forms a Schottky contact with the source; and
a gate electrode disposed directly or through a gate insulating layer on the semiconductor,
wherein a tunnel barrier insulating layer constituting a tunnel barrier is interposed between the semiconductor and the drain.

2. The spin transistor according to claim 1, wherein the tunnel barrier insulating layer contains at least one selected from the group consisting of SiO₂, Al₂O₃, NiO, CoFeO, MgO, CaF₂, and ZnO.

3. The spin transistor according to claim 1, wherein the source is a ferromagnetic metal,
wherein a conductivity type of the semiconductor is the n-type, wherein a work function φm of the ferromagnetic metal and a work function φs of the semiconductor satisfy a relation of φm>φs, and
wherein the source and the semiconductor form a Schottky contact, and a thickness of a potential barrier formed by the Schottky contact can be reduced to not more than a thickness in which a tunnel effect is caused according to a potential applied to the gate electrode.

4. The spin transistor according to claim 1, wherein the source is a ferromagnetic metal,
wherein a conductivity type of the semiconductor is the p-type,
wherein a work function φm of the ferromagnetic metal and a work function φs of the semiconductor satisfy a relation of φm<φs, and
wherein the source and the semiconductor form a Schottky contact, and a potential at a lower end of a conduction band of the semiconductor can be increased so as to permit flow of electrons from the source into the semiconductor, according to a potential applied to the gate electrode.

5. The spin transistor according to claim 1, further comprising control means for controlling a direction of magnetization of the drain.
